(19) United States
(12) Patent Application Publication
(10) Pub. No.: US 2005/0069148 A1
(43) Pub. Date: Mar. 31, 2005

(54) Audio apparatus

(76) Inventors: Akira Nishikawa, Kobe-shi (JP); Noboru Hidaka, Kobe-shi (JP)

Correspondence Address: CHRISTIE, PARKER & HALE, LLP, PO BOX 7068, PASADENA, CA, 91109-7068, US

(21) Appl. No.: 10/901,304

(22) Filed: Jul. 27, 2004

(30) Foreign Application Priority Data
Jul. 29, 2003 (JP) 2003-203233(PAT.)

(51) Int. Cl. H04R 1/02; H03G 1/00

(52) U.S. Cl. 381/89; 381/97

(57) ABSTRACT

The present invention relates to an audio apparatus that enables all listeners at seats within a vehicle compartment to obtain the same effect of sound spread feeling and sound image rise feeling. A front speaker FSP and a headlining speaker HSP are disposed separately in up and down directions relative to the listeners within the vehicle compartment. The apparatus delays the output time of sound from a speaker that is located at a shorter distance to the listeners than distances from other speakers to these listeners. When the listeners listen to sounds from the speakers FSP and HSP, the delay time is set based on a largest difference between the arrival time of the sound from the speaker FSP to each listener and the arrival time of the sound from the speaker HSP to the same listener, among all arrival-time differences. When the delay time is set longer, the listeners can secure a sound image forward-location feeling.

### CROSS-REFERENCE TO RELATED APPLICATION

This application claims the priority of Japanese Patent Application No. 2003-203233, filed on Jul. 29, 2003.

### BACKGROUND OF THE INVENTION

1. Field of the Invention

The present invention relates to an audio apparatus capable of correcting audibility of outputs from a plurality of speakers disposed above and below listeners within an automobile. Particularly, the invention relates to an audio apparatus that has a plurality of speakers including front speakers and speakers directly installed on a headlining board of the vehicle, which can improve the realistic sensation effect of sound for the listeners, can improve sound image, and can stereophonically reproduce sound by correcting audibility at the front seat and the back seat of the vehicle.

2. Description of the Related Art

An audio apparatus that drives speakers to acoustically reproduce a music or voice is conventionally used in a vehicle or a passenger vehicle. The speakers that are connected to the audio apparatus include front speakers embedded in front seat doors and rear speakers on a rear tray, for example. These speakers are usually set and installed to correspond to at least the front seat and the back seat for audibility purposes.

To produce stereo signals, a left channel speaker is fitted to the left end of the front panel, and a right channel speaker is fitted to the right end of the front panel in the vehicle compartment. From the driver's viewpoint, these speakers are arranged disproportionately. For example, the right speaker is nearer the driver than the left speaker. In this case, sound waves from the right speaker reaches the driver earlier than the sound waves from the left speaker. Consequently, the sound image is disproportionately positioned at the right side, although the sound image must be positioned at the front for stereo reproduction. In order to solve this problem, it is usual to delay the signal from the right speaker thereby making both signals from the left and right speakers reach the driver at the same time.

However, because the vehicle compartment is a closed narrow space, reflection occurs in a short time, causing interference between the sound waves, which makes transmission characteristics of the waves, to the listening position, very complex. Further, because the driver listens to music at a left-right asymmetrical position relative to the speaker positions, transmission characteristics of the waves from these speakers are greatly different. There have been various proposals to remove adverse effect of the stereo reproduction within the vehicle compartment, and improve the acoustic characteristics within the vehicle compartment.

A stereo reproducing apparatus is proposed in Japanese Patent Application Unexamined Publication No. 6-141440, for example. This stereo reproducing apparatus has left and right front speakers and left and right rear speakers within a vehicle compartment. A band filter having band cutoff characteristics of low order and a delay processor are connected in series in the apparatus. This is further connected to a band filter having band cutoff characteristics of high order. With this arrangement, even when a voice band signal is set to a normal position, delay amplitude characteristics are held flat, and the sound image of the voice band is positioned at the front of the driver within the compartment with the distorted speaker positions.

Japanese Patent Application Unexamined Publication No. 2001-236077 discloses a vehicle audio system, in which a microphone is provided in addition to the speakers. A delay unit is used to make sounds from the speakers reach the microphone at substantially the same time, thereby reducing the sense of discomfort in the audibility and improving the sound quality.

Further, the sound volume of the speakers disposed around inside the vehicle compartment and the output delay time are suitably set, thereby forming an optimum acoustic field. However, an optimum acoustic field cannot be formed at plural positions. Therefore, Japanese Patent Application Unexamined Publication No. 2001-286000 discloses the following audio system. A sound field correcting speaker set including four speakers facing four directions is disposed on the center headlining of the compartment. A filter of which sound volume ratio and sound output timing are adjusted independently is connected to each of eight speakers including the four surrounding speakers. The audio system outputs sound based on this arrangement.

This audio system can form optimum sound fields for four seats in the vehicle. The filter of each speaker is set in advance by matching the state of the mute of the speakers disposed around. At the mute detection time, the filter is selected, and the sound fields of other positions are not changed. Therefore, sound fields that are optimum at plural positions are formed respectively within the compartment. Therefore, all the persons sitting in the compartment can listen to the audio in individually optimum sound fields. For example, one person sitting at the right back seat or the left back seat can listen to the audio in similar optimum sound fields.

Japanese Utility Model Registration Application Unexamined Publication No. 6-45865 proposes a disposition of a speaker on the headlining of the vehicle compartment to form a better sound field having sufficiently heavy low sound, in addition to the speakers within the front seat doors and on the rear tray.

When the normal speakers are fitted to the compartment, there is a constraint to the speaker fitting positions because the speakers have a large diameter. The proposed speaker is designed to solve this problem. According to this proposal, a vibrator is directly fitted to the headlining board instead of the speaker having the large diameter, thereby forming a speaker using a part of the headlining board as a diaphragm.

According to the conventional technique, the doors and the trunk room are used as an enclosure in order to obtain the heavy low sound produced by the speaker of a large diameter. The heavy low sound is intensified based on the resonance of the enclosure. According to other conventional technique, what is called a digital signal processor is used to process a signal to intensify the heavy low sound.

According to these conventional techniques, however, it is difficult to sufficiently compensate for the shortage of the heavy low sound attributable to the diameters of the speakers. Further, the distances from the speakers embedded in the doors and the distances from the speakers mounted on the rear tray to the listeners sitting at the front seats and the back seats respectively are greatly different. This results in a large decline in the balance of the sound fields. Further, acoustics of the speakers embedded in the doors are emitted from below the listening position, causing a shortage in effective acoustic at the sound image position. This problem results in inability to reproduce acoustics having realistic sensation.

Japanese Utility Model Registration Application Unexamined Publication No. 6-45865 discloses the following vehicle speakers in consideration of the above problems. With at least a part of the headlining board of the vehicle used as a diaphragm, a speaker main body capable of reproducing at least the bass is fitted to the headlining such that the opening faces the vehicle compartment. With this arrangement, the bass can be reproduced, and the installation of the speaker on the headlining can enhance the realistic sensation. As a result, a better sound field can be formed within the compartment.

As explained above, various measures are taken to form a sound field that is optimum at each seat within the compartment, by improving the acoustic characteristics within the compartment at the time of stereo reproducing sound with a plurality of speakers disposed in the limited space.

Japanese Patent Application Unexamined Publication No. 6-141400 discloses a stereo reproducing apparatus that locates the sound image of the voice band in front of the driver, when the speaker position relative to the driver is slanted in the horizontal direction. Japanese Patent Application Unexamined Publication No. 2001-236077 discloses a vehicle audio system which improves sound quality by obtaining the frequency characteristics and the group delay time characteristics of the sound pressure level corresponding to the listening position. Japanese Patent Application Unexamined Publication No. 2001-286000 discloses an audio system that can form optimum sound fields at plural positions by selecting eight speakers including a sound field correcting speaker set.

According to the speaker apparatuses proposed using these techniques, the left and right front speakers are fitted to the front panel within the vehicle compartment. Because these speakers are disposed near the listeners' positions, the sound image of the outputs from the left and right speakers is formed, relatively, at the front of the listeners. Therefore, the listeners little feel the sense of discomfort relevant to the position of the sound image from the viewpoint of audibility.

On the other hand, when the conventionally proposed techniques of forming the optimum sound field and improving the sound quality are applied to the left and right front speakers that are fitted to the lower side of the front doors in the compartment as disclosed in Japanese Utility Model Registration Application No. 6-45865, the following problem occurs. Because the left and right front speakers are at a lower position than the listeners' position, the sound image is at a lower position than the listeners' position, losing the realistic sensation of the audio reproduction, even if the left and right front speakers can reproduce satisfactory stereo sound.

According to the speaker apparatus proposed in Japanese Utility Model Registration Application Unexamined Publication No. 6-45865, front speakers are fitted to the lower side of the left and right front doors. Further, a bass speaker is provided directly on the headlining board of the vehicle compartment. This speaker apparatus improves the realistic sensation based on the addition of the bass speaker, but does not raise the position of the sound image of the left and right front speakers from the lower side to the front of the listeners' position.

According to the techniques proposed in the patent literature, complex set circuits and many speakers are necessary to form optimum sound fields at plural positions within the vehicle compartment, which results in a cost increase. Further, because the circuits and the speakers need to be set by matching the individual listening positions, the listeners are forced to carry out a complex operation, which is troublesome.

It is an object of the present invention to provide an audio apparatus that drives front speakers and speakers fitted to the upper side and the lower side of the headlining board of a vehicle compartment in order to form a stereo reproduction space in the compartment, wherein the sound output from the speakers fitted to the headlining is delayed by a predetermined time from the sound output from the front speakers, thereby improving the spread feeling of sound, a rise in the sound image that the listeners feel, and enabling the listeners to obtain the similar effect at any listening position in the vehicle compartment.

### SUMMARY OF THE INVENTION

In order to solve the above problems, according to one aspect of the present invention, an audio apparatus comprises an output unit that outputs a first sound signal to drive a first speaker and a second sound signal to drive a second speaker disposed separately from the first speaker in a high and low positional relationship, and a control unit that controls the outputs of the first sound signal and the second sound signal, wherein the control unit delays one of the first sound signal and the second sound signal that are output to the first speaker and the second speaker whichever is positioned at a shorter distance from a listener, by a predetermined time from the other sound signal.

When the first speaker or the second speaker is positioned at the opposite side of the second speaker or the first speaker relative to the listener, the control unit sets the time delay from the second sound signal or the first sound signal longer than the predetermined time by a predetermined length. When a plurality of listeners listen to the sounds output from the first speaker and the second speaker, the control unit sets the predetermined time based on a largest difference between the arrival time of the sound output from the first speaker to each listener and the arrival time of the sound output from the second speaker to the same listener, among all arrival-time differences.

Each of the first sound signal and the second sound signal includes a stereo reproduction sound signal to drive the first speaker and the second speaker that are structured as stereo speakers respectively.

According to another aspect of the present invention, an audio apparatus comprises an output unit that outputs a first sound signal and a second sound signal to drive a first speaker and a second speaker disposed separately from the first speaker in a high and low positional relationship within a vehicle compartment, and a control unit that controls the outputs of the first sound signal and the second sound signal, wherein the control unit delays one of the first sound signal and the second sound signal that are output to the first speaker and the second speaker whichever is positioned at a shorter distance from a listener, by a predetermined time from the other sound signal.

When the first speaker or the second speaker is positioned at the opposite side of the second speaker or the first speaker relative to the listener, the control unit sets the time delay from the second sound signal or the first sound signal longer than the predetermined time by a predetermined length. When a plurality of listeners listen to the sounds output from the first speaker and the second speaker, the control unit sets the predetermined time based on a largest difference between the arrival time of the sound output from the first speaker to each listener and the arrival time of the sound output from the second speaker to the same listener, among all arrival-time differences.

Each of the first sound signal and the second sound signal includes a stereo reproduction sound signal to drive the first speaker and the second speaker that are structured as stereo speakers respectively.

The second sound signal is output to the second speaker disposed on the headlining board of the vehicle compartment. The first sound signal is output to the first speaker disposed at a lower part of the front door of the vehicle compartment. Alternately, the first sound signal is output to the first speaker disposed at a rear part of the vehicle compartment.

The second sound signal is used to drive the second speaker having a vibrator that directly vibrates a headlining board of the headlining.

The control unit holds arrival-time difference information concerning sounds output from the first speaker and the second speaker corresponding to a plurality of seats within the vehicle compartment, and sets the predetermined time based on a selected arrival-time difference.

The control unit sets the predetermined time based on a largest difference between the arrival time of the sound output from the first speaker to each listener and the arrival time of the sound output from the second speaker to the same listener, among all arrival-time differences corresponding to a plurality of seats within the vehicle compartment, and outputs the second sound signal that is delayed by the predetermined time.

The control unit sets the time delay from the second sound signal longer than the predetermined time by a predetermined length, and outputs the second sound signal that is delayed by the predetermined time.

### BRIEF DESCRIPTION OF THE DRAWINGS

Other features, objects and advantages of the present invention will become apparent from the following description of preferred embodiments with reference to the drawings in which like reference characters designate like or corresponding parts throughout several views.

FIG. 1 is a diagram for explaining the audibility correction principle in an audio apparatus according to the present invention;

FIG. 2 is a diagram for explaining a schematic block configuration of a stereo reproduction audio apparatus according to the present invention;

FIG. 3 is a diagram for explaining a state of correcting audibility to obtain the same effect at the front and back seats in a vehicle stereo reproduction audio apparatus according to the present invention;

FIG. 4 is a diagram for explaining a state that a conventional vehicle audio apparatus is fitted to a headlining interior board of the vehicle;

FIG. 5 is a vertical cross-sectional view of a conventional vehicle speaker;

FIG. 6 is a diagram for explaining a state that a headlining speaker is disposed near the front seat; and

FIG. 7 is a diagram for explaining a state that a headlining speaker is disposed near the back seat.

### DESCRIPTION OF THE PREFERRED EMBODIMENTS

An audio apparatus according to the embodiments of the present invention will be explained with reference to the drawings. The audio apparatus according to the embodiments is explained to raise a sound image based on the layout of a plurality of speakers for application to a vehicle compartment. However, when a part of the speakers needs to be disposed at a lower position than the listeners' position to form a stereo reproduction space with a raised sound image, and also when another speaker needs to be fitted to a higher position than the listeners' position, the audio apparatus according to the embodiments can be also applied to a space or a room other than the vehicle compartment.

In vehicles recently available, most front speakers are fitted to a lower part of the front doors, as disclosed in Japanese Utility Model Registration Application Unexamined Publication No. 6-45865. In order to raise a sound image, the audio apparatus according to the embodiments requires the installation of a speaker on the headlining board of the vehicle compartment in addition to the front speakers positioned at a lower side. Therefore, considering the fact that the speaker fitted to the headlining is not cumbersome, the speaker for direct fitting to the headlining disclosed in Japanese Utility Model Registration Application Unexamined Publication No. 6-45865 is employed for the audio apparatus according to the embodiments.

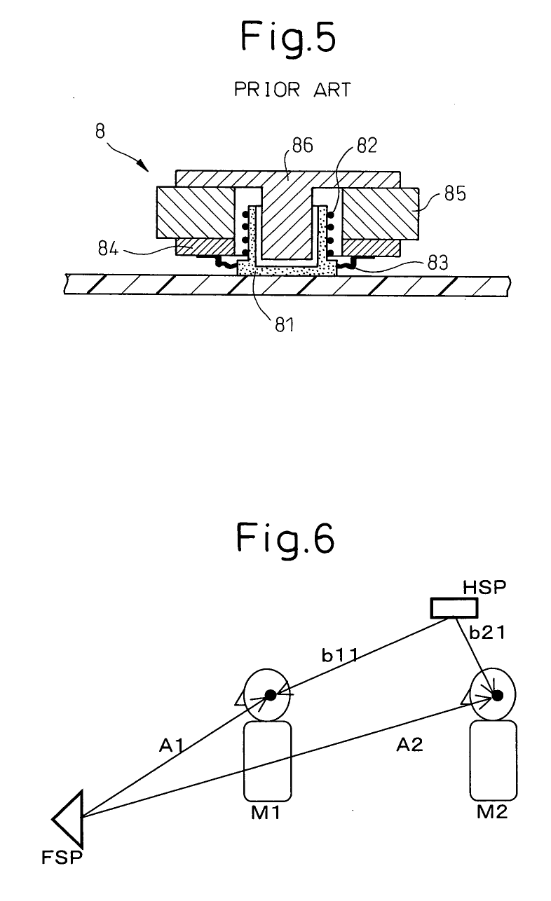

The speakers described in Japanese Utility Model Registration Application Unexamined Publication No. 6-45865 will be explained with reference to FIG. 4 and FIG. 5. FIG. 4 is a longitudinal sectional view of a part of a vehicle showing a state that a speaker for direct fitting to the headlining board (hereinafter referred to as a headlining speaker) is built into the vehicle. Front seats 3 including a driver seat, and back seats 4 are provided within the compartment of a vehicle 1. Front speakers 6 are embedded to a lower part of front doors near the front seats 3. Rear speakers are mounted on a rear tray near the back seats 4. The headlining of the vehicle 1 includes an outside plate 2 and a headlining board 5. A vibrator 8 described later is fitted to near the center of the headlining board 5 to form the speaker.

FIG. 5 is an enlarged cross-sectional view of the surrounding of the vibrator 8 that is directly fitted to the headlining board 5 to construct the speaker. The vibrator 8 forms an external magnetic circuit that sandwiches a ring magnet 85 between a plate 84 and a bed plate of a pole piece. A voice coil 82 is provided in a gap between the pole piece 86 and the plate 84 that form the magnetic circuit. The voice coil 82 is wound around a bobbin 81, and a seat of the bobbin 81 is fixed to the headlining board 5. A damper 83 fitted to the plate 84 is fixed to the seat of the bobbin 81.

The headlining board 5 itself plays the role of a diaphragm. Therefore, when an alternate current signal is given to the voice coil 82, this causes the vibration of the headlining board 5 that is connected to the bobbin 81 around which the voice coil 82 is wound. Consequently, acoustic corresponding to the alternate current signal can be generated. While the vibrator 8 can be fitted to between the outer plate 2 and the headlining board 5, alternately, the vibrator 8 can be fitted to the headlining board 5 facing the inside of the vehicle compartment, thereby obtaining a similar effect.

The headlining speaker described in Japanese Utility Model Registration Application Unexamined Publication No. 6-45865 can secure a large area of the diaphragm using the headlining board 5. Therefore, this speaker is used to reproduce heavy low sound. However, it is confirmed that a stereo speaker apparatus can be formed using the headlining board as a diaphragm that is directly driven based on stereo signals, when the stereo signals are supplied to two vibrators that are fitted to the headlining board with a predetermined distance between the vibrators. This predetermined distance is set to a size of about 80 to 120 centimeters that enables the seated listeners to obtain a stereophonic feeling in the vehicle.

The headlining speaker needs to be fitted to a flat portion of the headlining because a part of the headlining board is used as the diaphragm by installing the vibrators directly to the headlining board. Usually, a vehicle headlining board has a sharp curved portion for the convenience of building the headlining board into the headlining. Therefore, the vibrators of the headlining speaker are installed on the flat portion of the headlining board by avoiding the curved portion that does not function as a diaphragm.

The speaker apparatus for the stereo reproduction audio apparatus according to the present embodiment employs the above headlining speaker as the rear speaker, in place of the rear speaker mounted on the rear part of the vehicle compartment shown in FIG. 4, because of the need for installing the speaker at a higher position than the front speakers that are positioned at a lower side than the listening position. In the present embodiment, the headlining speaker is preferable for the rear speaker because the stereo apparatus is applied to a vehicle compartment. However, when the stereo apparatus is applied to a space or a room other than the vehicle compartment, the headlining speaker can be applied to a headlining board when the headlining board is available. When the headlining board is not available, a normal speaker can be fitted to a higher position for use as a rear speaker.

When the headlining speaker is installed on the vehicle headlining board, there is an effect that the sound spread feeling within the vehicle compartment can be improved, and the sound image formed by the front speaker can be raised. However, generally, a passenger vehicle has passenger front seats and back seats in addition to the driver seat as shown in FIG. 4. Therefore, depending on the position of installing the headlining speaker on the vehicle headlining, the effect of improvement in sound spread feeling and a rise of a sound image cannot be obtained at the same level at both front and back seats.

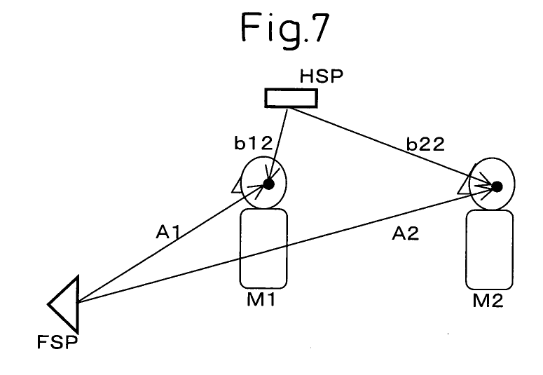

This problem will be explained with reference to FIG. 6 and FIG. 7. FIG. 6 is a diagram illustrating a state that the headlining speaker is installed near a listener at the front seat, and FIG. 7 is a diagram illustrating a state that the headlining speaker is installed near a listener at the back seat.

In FIG. 6, a headlining speaker HSP is installed on the headlining board near a listener M2 at the back seat and far from a listener M1 at the front seat. Therefore, the weight of the effect of improvement in sound spread feeling and a rise of a sound image is placed on the front seat. On the other hand, the sound from the headlining speaker HSP is ruling for the listener M2 at the back seat. This is because a distance b21 between the listener M2 and the headlining speaker HSP is shorter than a distance between a front speaker FSP and the listener M2.

On the other hand, in FIG. 7, the headlining speaker HSP is installed on the headlining board near the listener M1 at the front seat and far from the listener M2 at the back seat. Therefore, the weight of the effect of improvement in sound spread feeling and a rise of a sound image is placed on the back seat. However, the sound from the headlining speaker HSP is stronger for the listener M1 at the front seat. This is because a distance b12 between the listener M1 and the headlining speaker HSP is shorter than a distance A1 between the front speaker FSP and the listener M1.

Depending on the installation position of the headlining speaker HSP, the audibility at the front seat and the audibility at the back seat are not the same. The headlining speaker HSP is positioned at the front of the listener M2 who is at the back seat, both in FIG. 6 and FIG. 7. Therefore, the sound image formed by the front speaker FSP and the headlining speaker HSP is located at the front of the listener M2. Consequently, the listener M2 can secure a relatively satisfactory stereo feeling.

On the other hand, the headlining speaker HSP is positioned at the back of the listener M1 in both FIG. 6 and FIG. 7. Therefore, the sound image formed by the front speaker FSP and the headlining speaker HSP is located above the listener M1. Consequently, although the listener M1 can obtain a sound spread feeling, the listener M1 cannot secure a sound field that satisfies a stereo feeling.

In order to enable both the listener M1 and the listener M2 to obtain the same effect of the sound spread feeling, the sound image rise feeling, and the sound image forward location feeling, the following arrangement is necessary. When the front speaker FSP is installed at a lower side of the front door, the headlining speaker HSP needs to be installed on the headlining higher than the front speaker FSP.

However, the vehicle headlining usually covers at least only a portion above the front seat and the back seat. Depending on the setting of the sun roof, there is no room in the headlining for installing the headlining speaker HSP.

Depending on the construction of a passenger vehicle, the headlining board extends toward the front of the front seat. However, even if the headlining speaker HSP is installed, the sound image becomes far from the back seat, and the sound lacks vigor for the listener at the back seat. In this case, the installation of the headlining speaker HSP has little meaning.

Therefore, the vehicle headlining has a limited range for installing the headlining speaker. Consequently, when the headlining speaker HSP is installed on the headlining, the front speaker FSP fitted to a lower side of the front door and the headlining speaker HSP have difficulty in enabling both the listener M1 and the listener M2 to obtain the same effect of the sound spread feeling, the sound image rise feeling, and the sound image forward location feeling, as shown in FIG. 6 and FIG. 7.

To overcome the above difficulty, the audio apparatus according to the present embodiment utilizes the Haas effect to achieve a stereo reproduction using the front speaker FSP fitted to a lower side of the front door and the headlining speaker HSP. According to the Haas effect, a sound arrival time to the front seat listener M1 and a sound arrival time to the back seat listener M2 are adjusted. This adjustment enables both the listener M1 and the listener M2 to obtain the same effect for all of the sound spread feeling, the sound image rise feeling, and the sound image forward location feeling, even in the above situation.

The principle of audibility correction that adjusts the time of sound arrival to the listeners to enable both the listeners at the front and back seats to obtain the same effect of the sound spread feeling, the sound image rise feeling, and the sound image forward location feeling will be explained with reference to FIG. 1. It is assumed that the front speaker FSP is disposed at a lower part of the front door and below the listener M1, and the headlining speaker HSP is installed at the center of the vehicle headlining as an optimum installation position.

The Haas effect (i.e., leading sound effect) is a phenomenon that a sound image is formed in a direction of sound that first reaches the ears of a listener when the same sound is emitted from a plurality of sound sources. This phenomenon occurs when a difference between sound arrival times from these sound sources is 1 to 30 microseconds. According to the present embodiment, when the speakers and the listeners are positioned as shown in FIG. 1, this Haas effect is utilized to delay the sound output from the headlining speaker HSP from the sound output from the front speaker FSP by a predetermined time, thereby adjusting the time the sound reaches the listeners.

Consider the above adjustment for the listener M1, for example. Because the headlining speaker HSP is positioned at the back of the listener M1 relative to the front speaker FSP, the listener M1 can obtain the sound spread feeling and the sound image rise feeling, but cannot obtain the sound image forward location feeling. Therefore, the sound output from the headlining speaker HSP is delayed from the sound output from the front speaker FSP by a predetermined time. With this arrangement, there is an effect for the listener M1 that the apparent position of the headlining speaker HSP is farther than the front speaker FSP. Consequently, the sound from the front speaker FSP reaches the listener M1 earlier than the sound from the headlining speaker HSP. As a result, the listener M1 can secure the forward location feeling of the sound image.

To enable both the front seat listener M1 and the back seat listener M2 to obtain the same effect, the sound reach condition must be the same for the listener M1 and the listener M2. Assume that a distance from the listener M1 to the front speaker FSP and a distance from the listener M1 to the headlining speaker HSP are A1 and B1 respectively, and a distance from the listener M2 to the front speaker FSP and a distance from the listener M2 to the headlining speaker HSP are A2 and B2 respectively, as shown in FIG. 1. Setting the sound reach condition the same for both the listener M1 and the listener M2 means that the distances of the speakers satisfy a relationship of (A1−B1)=(A2−B2).

The disposition of the speakers that satisfies this relationship has the problems as described above. When the sound output from one speaker is delayed from the sound output from the other speaker, this has the effect of changing the apparent distance of the former speaker as explained above. Therefore, by utilizing this effect, the sound output from the headlining speaker HSP is delayed from the sound output from the front speaker FSP by a predetermined time so that the sound arrival time differences become the same for the listener M1 and the listener M2.

As explained above, by delaying the sound output, the same effect can be obtained for both the listener M1 and the listener M2. Moreover, in the speaker layout condition as shown in FIG. 1, the headlining speaker can be installed at a selected optimum position considering the speaker characteristics on the vehicle headlining, regardless of the listeners' audibility. Because the headlining speaker HSP is at a relatively close position for the back seat listener M2, the listener M2 can obtain a vigorous feeling of the sound.

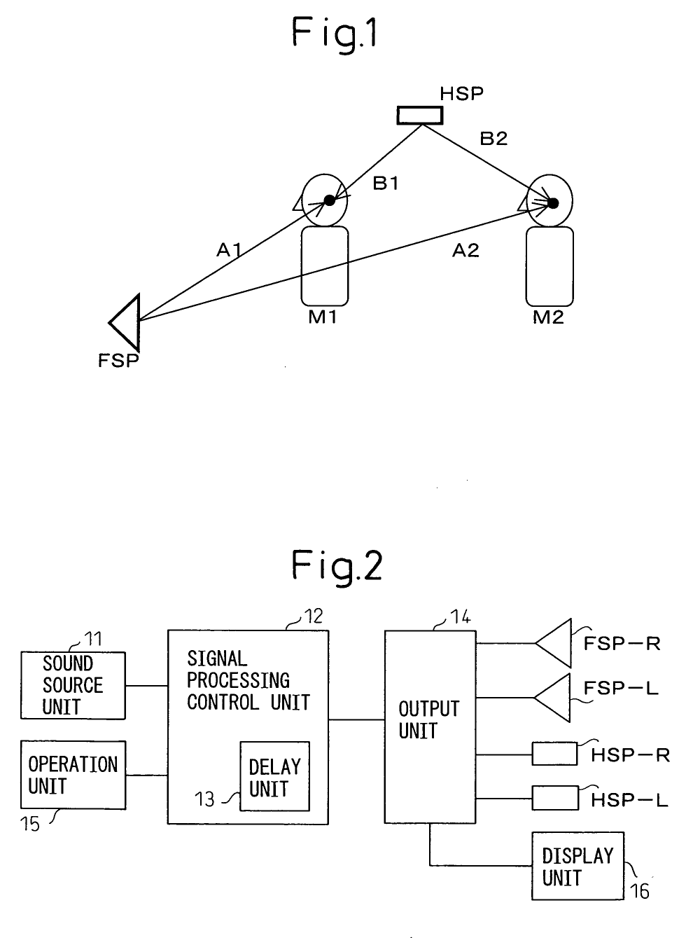

FIG. 2 is a schematic block configuration diagram of the audio apparatus according to the present embodiment using the speaker layout shown in FIG. 1. The layout of the speakers for the audio apparatus shown in FIG. 2 is designed for a small-size passenger vehicle. This vehicle includes left and right front speakers FSP-L and FSP-R provided at a lower part of the left and right front doors respectively, and two headlining speakers HSP-L and HSP-R installed on the headlining as rear speakers. This vehicle also includes a sound source unit 11, a signal processing control unit 12, an output unit 14, an operation unit 16, and a display unit 16 that constitute the audio apparatus to drive these speakers.

The sound source unit 11 includes a tape cassette player, a compact disk (CD), a magnetic disk (MD) reproduction player, or a digital versatile disk (DVD) reproduction player. The sound source unit 11 supplies a music signal or a voice signal from a selected sound source to the signal processing control unit 12.

The operation unit 15 selects a sound source of the sound source unit 11, and sets a sound reproduction condition. The operation unit 15 can further select or set an acoustic environment within the vehicle compartment such as an output status of each speaker.

The signal processing control unit 12 controls the entire audio apparatus. The signal processing control unit 12 demodulates a music signal or a voice signal transmitted from the sound source unit 11 following a condition input at the control unit 15, makes the output unit 14 output sound from each speaker, and makes the display unit 16 display a type of sound source, an output status of each speaker, and an audibility status of each seat within the vehicle compartment together with other image.

The signal processing control unit 12 further has a delay unit 13 inside. The delay unit 12 gives a predetermined time delay to a sound output to the headlining speaker HSP-L or HSP-R concerning the sound signal or the voice signal supplied from the sound source unit 11, according to a selected acoustic environment within the vehicle compartment. An optimum delay time can be set in advance for each vehicle type. Alternately, a user can select the on and off of the time delay in the operation unit 15. The delay time can be selected according to a type of sound source, or can be changed according to user's preference.

Although the audio apparatus shown in FIG. 2 has the configuration designed for a small-size vehicle, the audio apparatus can have rear-door speakers as rear speakers in addition to the headlining speaker, when the vehicle compartment is broader than that of the small-size vehicle such as a sedan or a one-box car. In this case, when a time delay is given to the sound output from the headlining speaker, a similar effect can be also obtained at all the seats within the vehicle compartment.

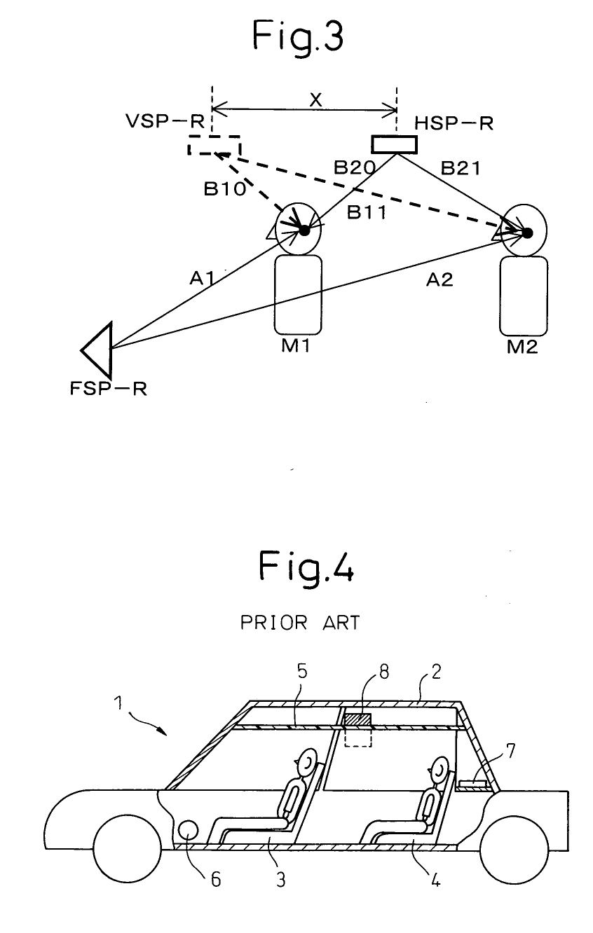

An example of the audio apparatus according to the embodiment having the configuration as shown in FIG. 2 that gives a time delay to sound outputs to the headlining speakers HSP-L and HSP-R will be explained with reference to FIG. 3. FIG. 3 is a schematic diagram showing a positional relationship between each speaker and the listeners. Because the drawing is simplified, the sizes in the drawing are not exactly the same as actual sizes.

In FIG. 3, the listener M1 is a driver of the small-size vehicle and is sitting at the front driver seat, and the listener M2 is sitting at the right back seat, that is, the seat immediately at the back of the driver. Respective listening positions are indicated with black circles. FIG. 3 is an illustration of a state observed at one side, showing the right front speaker FSP-R and the right headlining speaker HSP-R. Although the left front speaker FSP-L and the left headlining speaker HSP-L are also actually present, a redundant display of the left speakers is omitted to simplify the drawing.

A distance from the listening position of the listener M1 to the front speaker FSP-R and a distance from this listening position to the headlining speaker HSP-R are expressed as A1 and B11 respectively. A distance from the listening position of the listener M2 to the front speaker FSP-R and a distance from this listening position to the headlining speaker HSP-R are expressed as A2 and B21 respectively. Actual measured distances in the small-size vehicle are as follows.

| | A1 | A2 | B11 | B21 |
|---|---|---|---|---|
| Actual measured distance (mm) | 950 | 1690 | 325 | 820 |

The installation positions of the headlining speakers that enable the listeners at the front seat and the back seat to obtain a similar effect must satisfy the above relationship of (A1−B1)=(A2−B2). In other words, when the headlining speaker installed at an ideal position is expressed as VSP-R, this position is indicated by a square in a broken line in FIG. 3. When the headlining speaker is at this position, a relationship of (A1−B10)=(A2−B20) can be satisfied.

However, the headlining speaker HSP-R cannot be actually installed at this position indicated by the broken line square. Therefore, the headlining speaker HSP-R is installed at a position where the headlining speaker VSP-R at the ideal position is shifted by a distance X on the vehicle headlining. In this small-size vehicle, the distance X is set to 200 millimeters to secure a vigorous feeling at the back seat, and this position is selected as the optimum installation position. In this case, the head of the listener M1 is near the intermediate point of the distance X, and actual measured distances are as follows.

| | A1 | A2 | B11 | B21 |
|---|---|---|---|---|
| Actual measured distance (mm) | 950 | 1690 | 325 | 820 |

According to the ideal position indicated by the broken line in FIG. 3, the following distances are obtained.
A1−B10=645 (mm)
A2−B20=645 (mm)
However, due to the shift of the headlining speaker by the distance X, the actual measured distances become as follows.
A1−B11=625 (mm)
A2−B21=870 (mm)
Therefore, when the headlining speaker HSP-R is installed at this position, a similar effect cannot be obtained at the front seat and the back seat.

Impulse rise times of sounds from the front speakers FSP-L and FSP-R and the headlining speakers HSP-L and HSP-R at the positions of the listeners M1 and M2 are measured respectively. For the listener M1, the rise times are as follows.

| | HSP-R | HSP-L | FSP-R | FSP-L |
|---|---|---|---|---|
| Rise time (ms) | 3.0 | 4.29 | 4.81 | 5.85 |

For the listener M2, the rise times are as follows.

| | HSP-R | HSP-L | FSP-R | FSP-L |
|---|---|---|---|---|
| Rise time (ms) | 3.96 | 4.79 | 6.83 | 7.5 |

A difference between a sound arrival time from the front speaker FSP to the listener M1 position and a sound arrival time from the headlining speaker HSP to the listener M1 position are obtained for the right channel and the right channel respectively as follows.

| | (FSP-R) − (HSP-R) | (FSP-L) − (HSP-L) |
|---|---|---|
| Time difference (ms) | 1.81 | 1.56 |

A difference between a sound arrival time from the front speaker FSP to the listener M2 position and a sound arrival time from the headlining speaker HSP to the listener M2 position are obtained for the right channel and the right channel respectively as follows.

| | (FSP-R) − (HSP-R) | (FSP-L) − (HSP-L) |
|---|---|---|
| Time difference (ms) | 2.87 | 2.71 |

Consider the audibility of sounds from the front speaker FSP-R and the headlining speaker HSP-R to the listener M1 respectively as an example. When the sound output from the headlining speaker HSP-R is delayed from the sound output from the front speaker FSP-R by the time 1.81 microsecond based on the above time difference, the listener M1 can obtain the sound spread feeling and the sound rise feeling from the sounds output from the front speaker FSP-R and the headlining speaker HSP-R.

However, when the delay time of the sounds output from the headlining speakers HSP-R and HSP-L is set to 1.81 microseconds, the same spread feeling and the same sound image rise feeling cannot be obtained at all the listening positions, as is clear from the above result of time differences. In order to enable all the listeners at the listening positions to obtain the same spread feeling and the same sound image rise feeling, a time that covers all the above time differences of (FSP-R)−(HSP-R)=1.81, (FSP-L)−(HSP-L)=1.56, (FSP-R)-(HSP-R)=2.87, and (FSP-L)−(HSP-L)=2.71 can be set as the delay time of the sounds output from the headlining speakers HSP-R and HSP-L. For example, the delay time can be set to 3 microseconds.

When the delay unit 13 in the signal processing control unit 12 is set with 3 microseconds as the delay time of the sounds output from the headlining speakers HSP-R and HSP-L, all the listeners at the listening positions can obtain the same spread feeling and the same sound image rise feeling in the small-size vehicle. However, when the time delay of 3 microseconds is set, the listeners at the front seats can obtain the sound spread feeling and the sound image rise feeling but cannot obtain the sound image forward location feeling, because the headlining speaker HSP-L or HSP-R is positioned at the back of the listeners.

The delay time of the sounds output from the headlining speakers HSP-R and HSP-L is set to 6 microseconds that is two times the 3 microseconds, for example, with reference to the arrival time of sound from the front speaker FSP-L located at the farthest position from the listener M1 listening position. In this case, all the listeners at the listening positions can obtain the sound spread feeling and the sound image rise feeling. The listeners at the front seats can secure the sound image forward location feeling. Because the headlining speakers HSP-L and HSP-R are positioned near the listeners at the back seats, the listeners can secure the vigorous feeling of the sound.

While the distance X is set to 200 millimeters in the above example, this distance X is not necessarily fixed to this value. The sound output from the headlining speaker can be delayed based on a difference of sound arrival times obtained by measuring the impulse rise time from the speakers to listeners at plural seats, according to a speaker installation position on the headlining.

In the above example, the largest difference of arrival times obtained corresponding to the listening positions at plural seats is set as a predetermined time delay to the delay unit in the signal processing control unit. Alternately, the differences of arrival times obtained corresponding to the plural seats can be held in the control unit as sound arrival time difference information, and an arrival time difference is selected when necessary, and is set as a predetermined time delay.

In the above example, the headlining speakers are employed as rear speakers that are installed in the vehicle from the relationship of an upper and lower relationship within the vehicle compartment. Alternately normal flat speakers can be used in place of the headlining speakers.

While the audio apparatus according to the present embodiment is explained for application to a vehicle like a passenger vehicle, the application is not limited to the vehicle compartment. The audio apparatus can be applied to a room where a plurality of speakers cannot be installed in an ideal layout. When a time delay is given to the sound output from a selected speaker to thereby adjust the sound arrival time at listeners' positions, listeners can secure the sound spread feeling, the sound image rise feeling, and the sound image forward location feeling. The sound image forward location feeling can be adjusted by changing the time delay to be given.

As explained above, according to the present invention, the audio apparatus has a plurality of speakers installed at mutually separate upper and lower positions. Sound output from a speaker positioned nearer the listener is delayed by a predetermined time. When the speaker is positioned opposite to other speakers relative to the listener, the delay time of the sound output from the nearer speaker is set longer by a predetermined time. Therefore, the listener can secure the sound spread feeling, the sound image rise feeling, and the sound image forward location feeling.

When a plurality of listeners listen to sounds from a plurality of speakers, the predetermined delay time is set based on the largest difference of sound arrival times from the speakers to the listeners. Therefore, each listener can secure the sound spread feeling, the sound image rise feeling, and the sound image forward location feeling in the same effect.

1. An audio apparatus comprising:
an output unit that outputs a first sound signal to drive a first speaker and a second sound signal to drive a second speaker disposed separately from the first speaker in a high and low positional relationship; and
a control unit that controls the outputs of the first sound signal and the second sound signal, wherein
the control unit delays one of the first sound signal and the second sound signal that are output to the first speaker and the second speaker whichever is positioned at a shorter distance from a listener, by a predetermined time from the other sound signal.

2. The audio apparatus according to claim 1, wherein,
when the first speaker or the second speaker is positioned at the opposite side of the second speaker or the first speaker relative to the listener, the control unit sets the time delay from the second sound signal or the first sound signal longer than the predetermined time by a predetermined length.

3. The audio apparatus according to claim 1, wherein,
when a plurality of listeners listen to the sounds output from the first speaker and the second speaker, the control unit sets the predetermined time based on a largest difference between the arrival time of the sound output from the first speaker to each listener and the arrival time of the sound output from the second speaker to the same listener, among all arrival-time differences.

4. The audio apparatus according to claim 1, wherein
each of the first sound signal and the second sound signal includes a stereo reproduction sound signal to drive the first speaker and the second speaker that are structured as stereo speakers respectively.

5. The audio apparatus according to claim 2, wherein
each of the first sound signal and the second sound signal includes a stereo reproduction sound signal to drive the first speaker and the second speaker that are structured as stereo speakers respectively.

6. The audio apparatus according to claim 3, wherein
each of the first sound signal and the second sound signal includes a stereo reproduction sound signal to drive the first speaker and the second speaker that are structured as stereo speakers respectively.

7. An audio apparatus comprising:
an output unit that outputs a first sound signal and a second sound signal to drive a first speaker and a second speaker disposed separately from the first speaker in a high and low positional relationship within a vehicle compartment, and
a control unit that controls the outputs of the first sound signal and the second sound signal, wherein
the control unit delays one of the first sound signal and the second sound signal that are output to the first speaker and the second speaker whichever is positioned at a shorter distance from a listener, by a predetermined time from the other sound signal.

8. The audio apparatus according to claim 7, wherein,
when the first speaker or the second speaker is positioned at the opposite side of the second speaker or the first speaker relative to the listener, the control unit sets the time delay from the second sound signal or the first sound signal longer than the predetermined time by a predetermined length.

9. The audio apparatus according to claim 7, wherein,
when a plurality of listeners listen to the sounds output from the first speaker and the second speaker, the control unit sets the predetermined time based on a largest difference between the arrival time of the sound output from the first speaker to each listener and the arrival time of the sound output from the second speaker to the same listener, among all arrival-time differences.

10. The audio apparatus according to claim 7, wherein,
each of the first sound signal and the second sound signal includes a stereo reproduction sound signal to drive the first speaker and the second speaker that are structured as stereo speakers, respectively.

11. The audio apparatus according to claim 8, wherein
each of the first sound signal and the second sound signal includes a stereo reproduction sound signal to drive the first speaker and the second speaker that are structured as stereo speakers, respectively.

12. The audio apparatus according to claim 9, wherein
each of the first sound signal and the second sound signal includes a stereo reproduction sound signal to drive the first speaker and the second speaker that are structured as stereo speakers respectively.

13. The audio apparatus according to claim 7, wherein
the second sound signal is output to the second speaker disposed on the headlining board of the vehicle compartment.

14. The audio apparatus according to claim 8, wherein
the second sound signal is output to the second speaker disposed on the headlining board of the vehicle compartment.

15. The audio apparatus according to claim 9, wherein
the second sound signal is output to the second speaker disposed on the headlining board of the vehicle compartment.

16. The audio apparatus according to claim 13, wherein
the first sound signal is output to the first speaker disposed at a lower part of the front door of the vehicle compartment.

17. The audio apparatus according to claim 14, wherein
the first sound signal is output to the first speaker disposed at a lower part of the front door of the vehicle compartment.

18. The audio apparatus according to claim 15, wherein
the first sound signal is output to the first speaker disposed at a lower part of the front door of the vehicle compartment.

19. The audio apparatus according to claim 13, wherein
the first sound signal is output to the first speaker disposed at a rear part of the vehicle compartment.

20. The audio apparatus according to claim 14, wherein
the first sound signal is output to the first speaker disposed at a rear part of the vehicle compartment.

21. The audio apparatus according to claim 15, wherein
the first sound signal is output to the first speaker disposed at a rear part of the vehicle compartment.

22. The audio apparatus according to claim 13, wherein
the second sound signal is used to drive the second speaker having a vibrator that directly vibrates a headlining board of the headlining.

23. The audio apparatus according to claim 14, wherein
the second sound signal is used to drive the second speaker having a vibrator that directly vibrates a headlining board of the headlining.

24. The audio apparatus according to claim 15, wherein
the second sound signal is used to drive the second speaker having a vibrator that directly vibrates a headlining board of the headlining.

25. The audio apparatus according to claim 7, wherein
the control unit holds arrival-time difference information concerning sounds output from the first speaker and the second speaker corresponding to a plurality of seats within the vehicle compartment, and sets the predetermined time based on a selected arrival-time difference.

26. The audio apparatus according to claim 8, wherein
the control unit holds arrival-time difference information concerning sounds output from the first speaker and the second speaker corresponding to a plurality of seats within the vehicle compartment, and sets the predetermined time based on a selected arrival-time difference.

27. The audio apparatus according to claim 9, wherein
the control unit holds arrival-time difference information concerning sounds output from the first speaker and the second speaker corresponding to a plurality of seats within the vehicle compartment, and sets the predetermined time based on a selected arrival-time difference.

28. The audio apparatus according to claim 7, wherein
the control unit sets the predetermined time based on a largest difference between the arrival time of the sound output from the first speaker to each listener and the arrival time of the sound output from the second speaker to the same listener, among all arrival-time differences corresponding to a plurality of seats within the vehicle compartment, and outputs the second sound signal that is delayed by the predetermined time.

29. The audio apparatus according to claim 8, wherein
the control unit sets the predetermined time based on a largest difference between the arrival time of the sound output from the first speaker to each listener and the arrival time of the sound output from the second speaker to the same listener, among all arrival-time differences corresponding to a plurality of seats within the vehicle compartment, and outputs the second sound signal that is delayed by the predetermined time.

30. The audio apparatus according to claim 9, wherein
the control unit sets the predetermined time based on a largest difference between the arrival time of the sound output from the first speaker to each listener and the arrival time of the sound output from the second speaker to the same listener, among all arrival-time differences corresponding to a plurality of seats within the vehicle compartment, and outputs the second sound signal that is delayed by the predetermined time.

31. The audio apparatus according to claim 28, wherein
the control unit sets the time delay from the second sound signal longer than the predetermined time by a predetermined length, and outputs the second sound signal that is delayed by the predetermined time.

32. The audio apparatus according to claim 29, wherein
the control unit sets the time delay from the second sound signal longer than the predetermined time by a predetermined length, and outputs the second sound signal that is delayed by the predetermined time.

33. The audio apparatus according to claim 30, wherein
the control unit sets the time delay from the second sound signal longer than the predetermined time by a predetermined length, and outputs the second sound signal that is delayed by the predetermined time.
